(19) United States
(12) Patent Application Publication
(10) Pub. No.: US 2025/0068786 A1
(43) Pub. Date: Feb. 27, 2025

(54) Additive Manufacturing Simulation System and Method

(71) Applicant: Seurat Technologies, Inc., Wilmington, MA (US)

(72) Inventors: James A. DeMuth, Woburn, MA (US); Erik Toomre, Los Altos, CA (US)

(21) Appl. No.: 18/940,116

(22) Filed: Nov. 7, 2024

Related U.S. Application Data
(63) Continuation-in-part of application No. 15/415,680, filed on Jan. 25, 2017, now abandoned.
(60) Provisional application No. 62/289,824, filed on Feb. 1, 2016.

(51) Int. Cl. G06F 30/17; B33Y 50/00

(52) U.S. Cl. CPC G06F 30/17; B33Y 50/00

(57) ABSTRACT

An additive manufacturing method that can use a two-dimensional energy patterning system is disclosed. Information related to a part is provided, with the information including CAD files, material type, selected additive manufacturing process type, and tolerances of selected design features. Manufacture of a part is simulated and compared to selected design tolerance. If the simulated manufactured part is outside selected design tolerances, simulation parameters can be adjusted until results indicate the simulated manufactured part is within selected design tolerances. In certain embodiments, manufacturing the part uses a real-time sensor monitoring system, along with post processing analysis of selected design features to improve simulated manufacture of the part.

### CROSS-REFERENCE TO RELATED PATENT APPLICATION

This application is a continuation in part of U.S. patent application Ser. No. 15/415,680, filed Jan. 25, 2017, which claims the benefit of U.S. Provisional Patent Application No. 62/289,824, filed Feb. 1, 2016, both of which are hereby incorporated by reference in their entirety.

### TECHNICAL FIELD

The present disclosure relates generally to a system and method for simulation and additive manufacturing. In one embodiment, stress in additively manufactured parts is simulated and parameters adjusted until design tolerances are met.

### BACKGROUND

Traditional component machining often relies on removal of material by drilling, cutting, or grinding to form a part. In contrast, additive manufacturing, also referred to as 3D printing, typically involves sequential layer by layer addition of material to build a part. Beginning with a 3D computer model, an additive manufacturing system can be used to create complex parts from a wide variety of materials.

The powder bed fusion (PBF) technique for additive manufacturing of metals, ceramics, and plastics is well suited for manufacture of a wide range of parts. However, computationally modeling powder bed fusion parts is difficult. For example, thermal expansion and the buildup of internal stresses are difficult to computationally model in complex parts, but ignoring or failing to compensate for these issues can result in weak or failed parts.

Accurate modeling can involve capturing the effects of surface tension, photon absorption, emission, reflection, transmission, scattering, thermal conduction in the gas/powder particles/previous layer(s), advection of the gas, thermal expansion of the powder particles and the previous layer(s), phase change including melting, gasification, condensation, and solidification, and in cases of high temperature melting materials (such as metals/ceramics), thermal radiation heat transfer. Other physics such as gas photon absorption, buoyancy, and if ceramics are to be modeled accurately, chemistry needs to be involved.

Unfortunately, such physics modeling is generally too difficult for currently available explicit solution solvers, due in part to the exceedingly large number of interconnected variables that need to be solved implicitly. While such implicit solution methods can use various numerical analysis techniques, to solve the modeling problem a full multi-physics model is typically required. For example, Finite Element Analysis (FEA) can be used for static structural problems, and Computational Fluid Dynamics (CFD) for fluid flow. However, to accurately solve for the resultant stress distributions and geometry after an additively manufactured part has cooled, the thermal history of the part is required. Thermal history calculations require a full suite of physics modeling, which is not captured by conventional FEA and CFD analyses. Commonly available commercial modeling packages either lack the physics capabilities to model the additive manufacturing process in sufficient detail, or use of the required number of additional physics packages causes the solution time to grow to timescales of a month or more at which point it is of limited industrial use.

If the additive manufacturing process could be modeled in sufficient detail and fast enough for part prototyping and manufacture, appropriate accuracy on the alterations to key processing parameters could be made such that the “As-Printed” part equals the “As Desired” part.

### BRIEF DESCRIPTION OF THE DRAWINGS

Non-limiting and non-exhaustive embodiments of the present disclosure are described with reference to the following figures, wherein like reference numerals refer to like parts throughout the various figures unless otherwise specified.

FIG. 1A illustrates an additive manufacturing system;

FIG. 1B is a top view of a structure being formed on an additive manufacturing system;

FIG. 2 illustrates an additive manufacturing method;

FIG. 3A is a cartoon illustrating an additive manufacturing system including lasers;

FIG. 3B is a detailed description of the light patterning unit shown in FIG. 3A;

FIG. 3C is one embodiment of an additive manufacturing system with a “switchyard” for directing and repatterning light using multiple image relays;

FIG. 3D illustrates a simple mirror image pixel remapping;

FIG. 3E illustrates a series of image transforming image relays for pixel remapping; and

FIG. 3F illustrates an patternable electron energy beam additive manufacturing system;

FIG. 3G illustrates a detailed description of the electron beam patterning unit shown in FIG. 3F

FIG. 4 illustrates an embodiment of a simulation and additive manufacturing system;

FIG. 5 illustrates another embodiment of a simulation and additive manufacturing system with a remote simulation computer;

FIG. 6 illustrates optimized packing of multiple additively manufactured parts based in part on simulated thermal history;

FIG. 7 illustrates a defect library for a simulation and additive manufacturing system; and

FIG. 8 illustrates use of a part database to improve operation of a simulation and additive manufacturing system.

FIG. 9 illustrates an embodiment of a porosity unit cell applied to a part to be manufactured for use in the simulation and additive manufacturing system.

FIG. 10 illustrates a block diagram of the update process for the counter deformation calculations of the simulation.

### DETAILED DESCRIPTION

In the following description, reference is made to the accompanying drawings that form a part thereof, and in which is shown by way of illustrating specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The following detailed description is, therefore, not to be taken in a limiting sense.

An additive manufacturing system which has one or more energy sources, including in one embodiment, one or more laser or electron beams, are positioned to emit one or more energy beams. Beam shaping optics may receive the one or more energy beams from the energy source and form a single beam. An energy patterning unit receives or generates the single beam and transfers a two-dimensional pattern to the beam, and may reject the unused energy not in the pattern. An image relay receives the two-dimensional patterned beam and focuses it as a two-dimensional image to a desired location on a height fixed or movable build platform (e.g. a powder bed). In certain embodiments, some or all of any rejected energy from the energy patterning unit is reused.

In some embodiments, multiple beams from the laser array(s) are combined using a beam homogenizer. This combined beam can be directed at an energy patterning unit that includes either a transmissive or reflective pixel addressable light valve. In one embodiment, the pixel addressable light valve includes both a liquid crystal module having a polarizing element and a light projection unit providing a two-dimensional input pattern. The two-dimensional image focused by the image relay can be sequentially directed toward multiple locations on a powder bed to build a 3D structure.

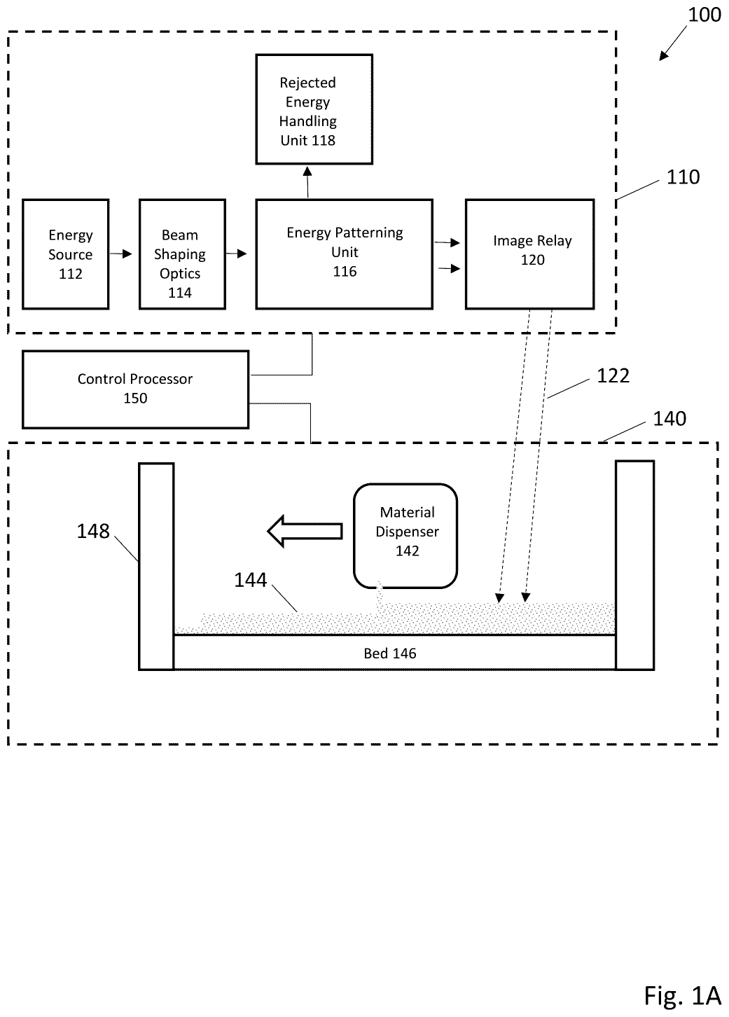

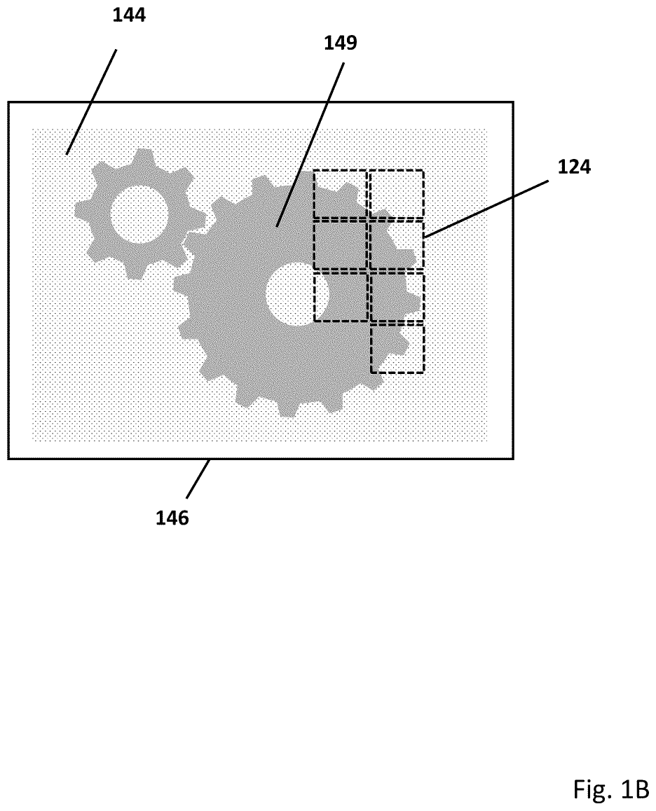

As seen in FIG. 1, an additive manufacturing system 100 has an energy patterning system 110 with an energy source 112 that can direct one or more continuous or intermittent energy beam(s) toward beam shaping optics 114. After shaping, if necessary, the beam is patterned by an energy patterning unit 116, with generally some energy being directed to a rejected energy handling unit 118. Patterned energy is relayed by image relay 120 toward an article processing unit 140, typically as a two-dimensional image 122 focused near a bed 146. The bed 146 (with optional walls 148) can form a chamber containing material 144 dispensed by material dispenser 142. Patterned energy, directed by the image relay 120, can melt, fuse, sinter, amalgamate, change crystal structure, influence stress patterns, or otherwise chemically or physically modify the dispensed material 144 to form structures with desired properties.

Energy source 112 generates photon (light), electron, ion, or other suitable energy beams or fluxes capable of being directed, shaped, and patterned. Multiple energy sources can be used in combination. The energy source 112 can include lasers, incandescent light, concentrated solar, other light sources, electron beams, or ion beams. Possible laser types include, but are not limited to: Gas Lasers, Chemical Lasers, Dye Lasers, Metal Vapor Lasers, Solid State Lasers (e.g. fiber), Semiconductor (e.g. diode) Lasers, Free electron laser, Gas dynamic laser, “Nickel-like” Samarium laser, Raman laser, or Nuclear pumped laser.

A Gas Laser can include lasers such as a Helium-neon laser, Argon laser, Krypton laser, Xenon ion laser, Nitrogen laser, Carbon dioxide laser, Carbon monoxide laser or Excimer laser.

A Chemical laser can include lasers such as a Hydrogen fluoride laser, Deuterium fluoride laser, COIL (Chemical oxygen-iodine laser), or Agil (All gas-phase iodine laser).

A Metal Vapor Laser can include lasers such as a Helium-cadmium (HeCd) metal-vapor laser, Helium-mercury (HeHg) metal-vapor laser, Helium-selenium (HeSe) metal-vapor laser, Helium-silver (HeAg) metal-vapor laser, Strontium Vapor Laser, Neon-copper (NeCu) metal-vapor laser, Copper vapor laser, Gold vapor laser, or Manganese (Mn/MnCl₂) vapor laser.

A Solid State Laser can include lasers such as a Ruby laser, Nd:YAG laser, NdCrYAG laser, Er:YAG laser, Neodymium YLF (Nd:YLF) solid-state laser, Neodymium doped Yttrium orthovanadate (Nd:YVO4) laser, Neodymium doped yttrium calcium oxoborateNd:YCa₄O(BO₃)³ or simply Nd:YCOB, Neodymium glass (Nd:Glass) laser, Titanium sapphire (Ti:sapphire) laser, Thulium YAG (Tm:YAG) laser, Ytterbium YAG (Yb:YAG) laser, Ytterbium: 2O₃ (glass or ceramics) laser, Ytterbium doped glass laser (rod, plate/chip, and fiber), Holmium YAG (Ho:YAG) laser, Chromium ZnSe (Cr:ZnSe) laser, Cerium doped lithium strontium (or calcium)aluminum fluoride (Ce:LiSAF, Ce:LiCAF), Promethium 147 doped phosphate glass (147Pm⁺³:Glass) solid-state laser, Chromium doped chrysoberyl (alexandrite) laser, Erbium doped anderbium-ytterbium co-doped glass lasers, Trivalent uranium doped calcium fluoride (U:CaF₂) solid-state laser, Divalent samarium doped calcium fluoride (Sm:CaF₂) laser, or F-Center laser.

A Semiconductor Laser can include laser medium types such as GaN, InGaN, AlGaInP, AlGaAs, InGaAsP, GaInP, InGaAs, InGaAsO, GaInAsSb, lead salt, Vertical cavity surface emitting laser (VCSEL), Quantum cascade laser, Hybrid silicon laser, or combinations thereof.

For example, in one embodiment a single Nd:YAG q-switched laser can be used in conjunction with multiple semiconductor lasers. In another embodiment, an electron beam can be used in conjunction with an ultraviolet semiconductor laser array. In still other embodiments, a two-dimensional array of lasers can be used. In some embodiments with multiple energy sources, pre-patterning of an energy beam can be done by selectively activating and deactivating energy sources.

Beam shaping unit 114 can include a great variety of imaging optics to combine, focus, diverge, reflect, refract, homogenize, adjust intensity, adjust frequency, or otherwise shape and direct one or more energy beams received from the energy source 112 toward the energy patterning unit 116. In one embodiment, multiple light beams, each having a distinct light wavelength, can be combined using wavelength selective mirrors (e.g. dichroics) or diffractive elements. In other embodiments, multiple beams can be homogenized or combined using multifaceted mirrors, microlenses, and refractive or diffractive optical elements.

Energy patterning unit 116 can include static or dynamic energy patterning elements. For example, photon, electron, or ion beams can be blocked by masks with fixed or movable elements. To increase flexibility and ease of image patterning, pixel addressable masking, image generation, or transmission can be used. In some embodiments, the energy patterning unit includes addressable light valves, alone or in conjunction with other patterning mechanisms to provide patterning. The light valves can be transmissive, reflective, or use a combination of transmissive and reflective elements. Patterns can be dynamically modified using electrical or optical addressing. In one embodiment, a transmissive optically addressed light valve acts to rotate polarization of light passing through the valve, with optically addressed pixels forming patterns defined by a light projection source. In another embodiment, a reflective optically addressed light valve includes a write beam for modifying polarization of a read beam. In yet another embodiment, an electron patterning device receives an address pattern from an electrical or photon stimulation source and generates a patterned emission of electrons.

Rejected energy handling unit 118 is used to disperse, redirect, or utilize energy not patterned and passed through the energy pattern image relay 120. In one embodiment, the rejected energy handling unit 118 can include passive or active cooling elements that remove heat from the energy patterning unit 116. In other embodiments, the rejected energy handling unit can include a “beam dump” to absorb and convert to heat any beam energy not used in defining the energy pattern. In still other embodiments, rejected beam energy can be recycled using beam shaping optics 114. Alternatively, or in addition, rejected beam energy can be directed to the article processing unit 140 for heating or further patterning. In certain embodiments, rejected beam energy can be directed to additional energy patterning systems or article processing units.

Image relay 120 receives a patterned image (typically two-dimensional) from the energy patterning unit 116 and guides it toward the article processing unit 140. In a manner similar to beam shaping optics 114, the image relay 120 can include optics to combine, focus, diverge, reflect, refract, adjust intensity, adjust frequency, or otherwise shape and direct the patterned image.

Article processing unit 140 can include a walled chamber 148 and bed 144, and a material dispenser 142 for distributing material. The material dispenser 142 can distribute, remove, mix, provide gradations or changes in material type or particle size, or adjust layer thickness of material. The material can include metal, ceramic, glass, polymeric powders, other melt-able material capable of undergoing a thermally induced phase change from solid to liquid and back again, or combinations thereof. The material can further include composites of melt-able material and non-melt-able material where either or both components can be selectively targeted by the imaging relay system to melt the component that is melt-able, while either leaving along the non-melt-able material or causing it to undergo a vaporizing/destroying/combusting or otherwise destructive process. In certain embodiments, slurries, sprays, coatings, wires, strips, or sheets of materials can be used. Unwanted material can be removed for disposable or recycling by use of blowers, vacuum systems, sweeping, vibrating, shaking, tipping, or inversion of the bed 146.

In addition to material handling components, the article processing unit 140 can include components for holding and supporting 3D structures, mechanisms for heating or cooling the chamber, auxiliary or supporting optics, and sensors and control mechanisms for monitoring or adjusting material or environmental conditions. The article processing unit can, in whole or in part, support a vacuum or inert gas atmosphere to reduce unwanted chemical interactions as well as to mitigate the risks of fire or explosion (especially with reactive metals).

Control processor 150 can be connected to control any components of additive manufacturing system 100. The control processor 150 can be connected to variety of sensors, actuators, heating or cooling systems, monitors, and controllers to coordinate operation. A wide range of sensors, including imagers, light intensity monitors, thermal, pressure, or gas sensors can be used to provide information used in control or monitoring. The control processor can be a single central controller, or alternatively, can include one or more independent control systems. The controller processor 150 is provided with an interface to allow input of manufacturing instructions. Use of a wide range of sensors allows various feedback control mechanisms that improve quality, manufacturing throughput, and energy efficiency.

FIG. 1B is a cartoon illustrating a bed 146 that supports material 144. Using a series of sequentially applied, two-dimensional patterned energy beam images (squares in dotted outline 124), a structure 149 is additively manufactured. As will be understood, image patterns having non-square boundaries can be used, overlapping or interpenetrating images can be used, and images can be provided by two or more energy patterning systems. In other embodiments, images can be formed in conjunction with directed electron or ion beams, or with printed or selective spray systems.

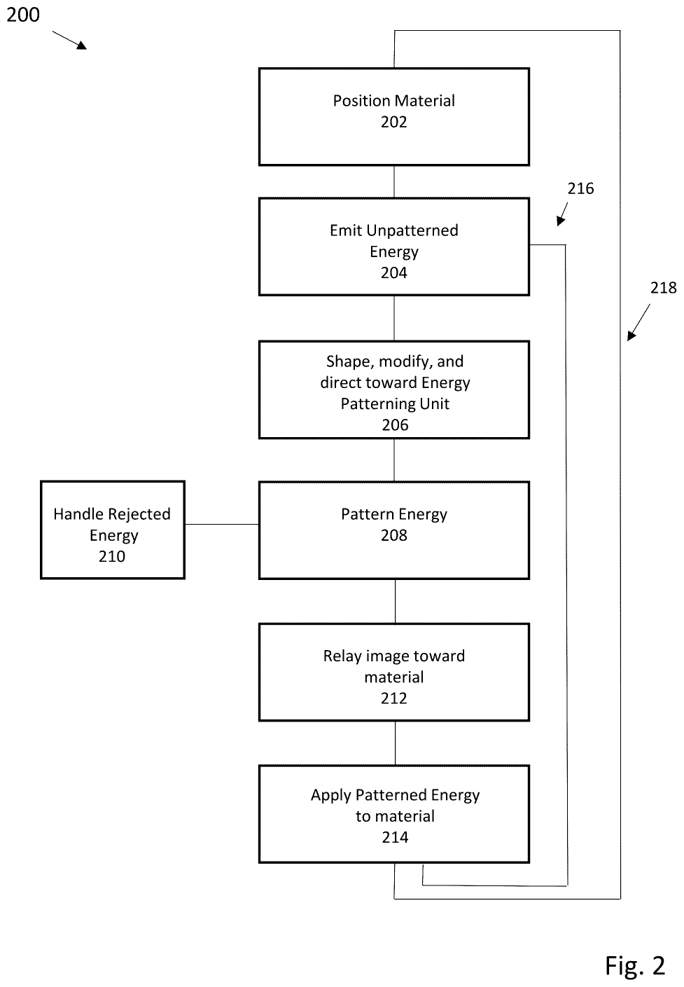

FIG. 2 is a flow chart illustrating one embodiment of an additive manufacturing process supported by the described optical and mechanical components. In step 202, material is positioned in a bed, chamber, or other suitable support. The material can be a powder capable of being melted, fused, sintered, induced to change crystal structure, have stress patterns influenced, or otherwise chemically or physically modified to form structures with desired properties.

In step 204, unpatterned energy is emitted by one or more energy emitters, including but not limited to solid state or semiconductor lasers, or electrical power supply flowing electrons down a wire. In step 206, the unpatterned energy is shaped and modified (e.g. intensity modulated or focused). In step 208, this unpatterned energy is patterned, with energy not forming a part of the pattern being handled in step 210 (this can include conversion to waste heat, or recycling as patterned or unpatterned energy). In step 212, the patterned energy, now forming a two-dimensional image is relayed toward the material. In step 214, the image is applied to the material, building a portion of a 3D structure. These steps can be repeated (loop 218) until the image (or different and subsequent image) has been applied to all necessary regions of a top layer of the material. When application of energy to the top layer of the material is finished, a new layer can be applied (loop 216) to continue building the 3D structure. These process loops are continued until the 3D structure is complete, when remaining excess material can be removed or recycled.

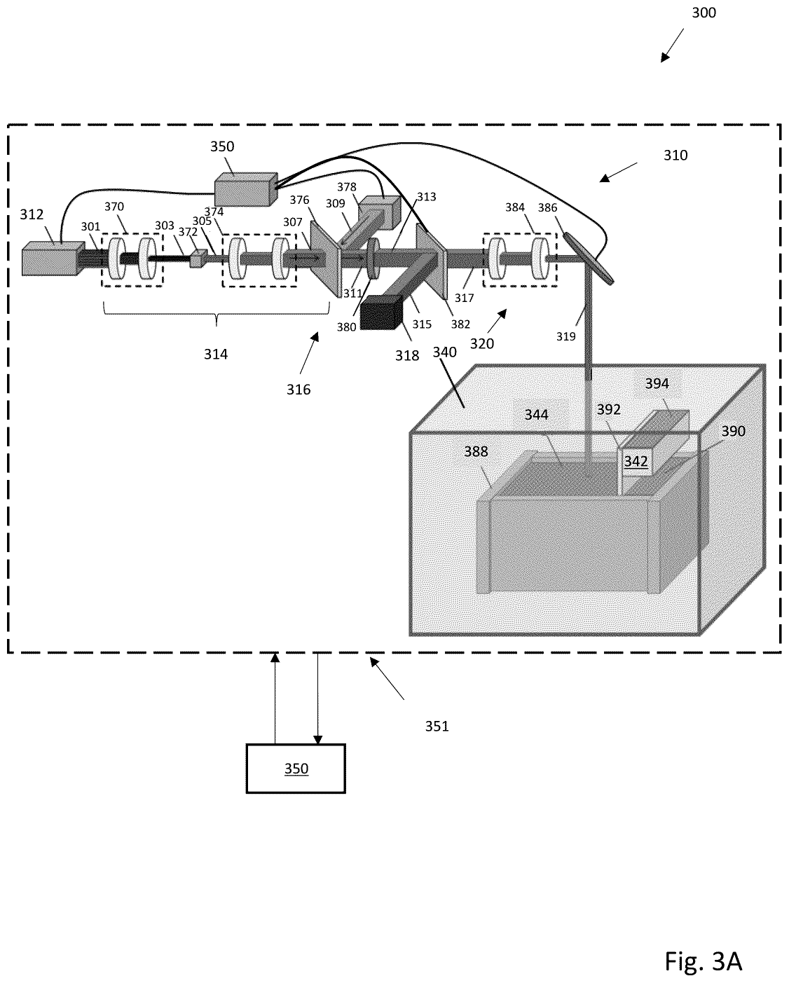

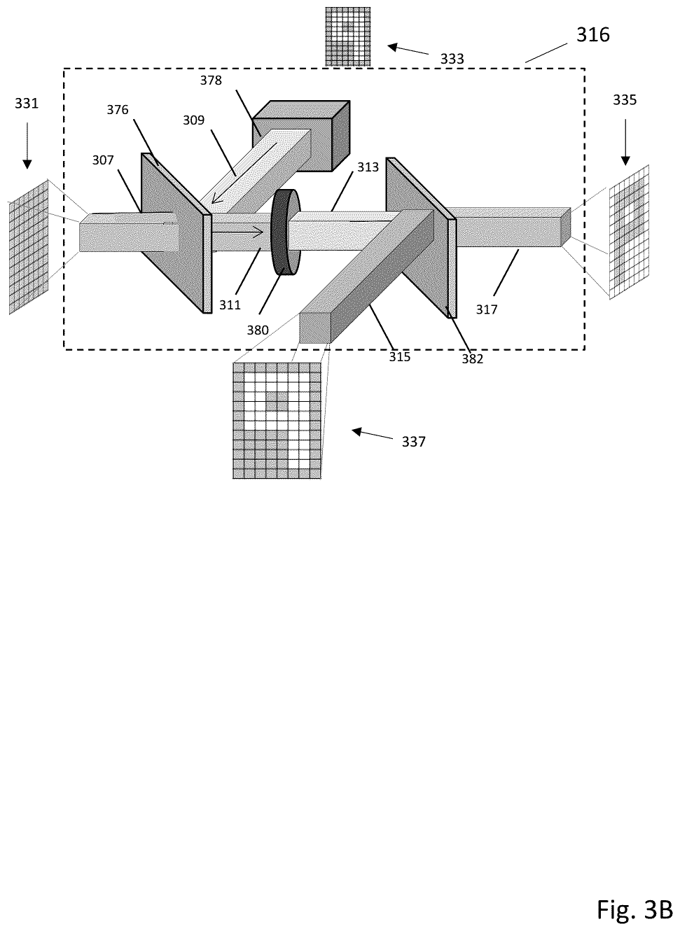

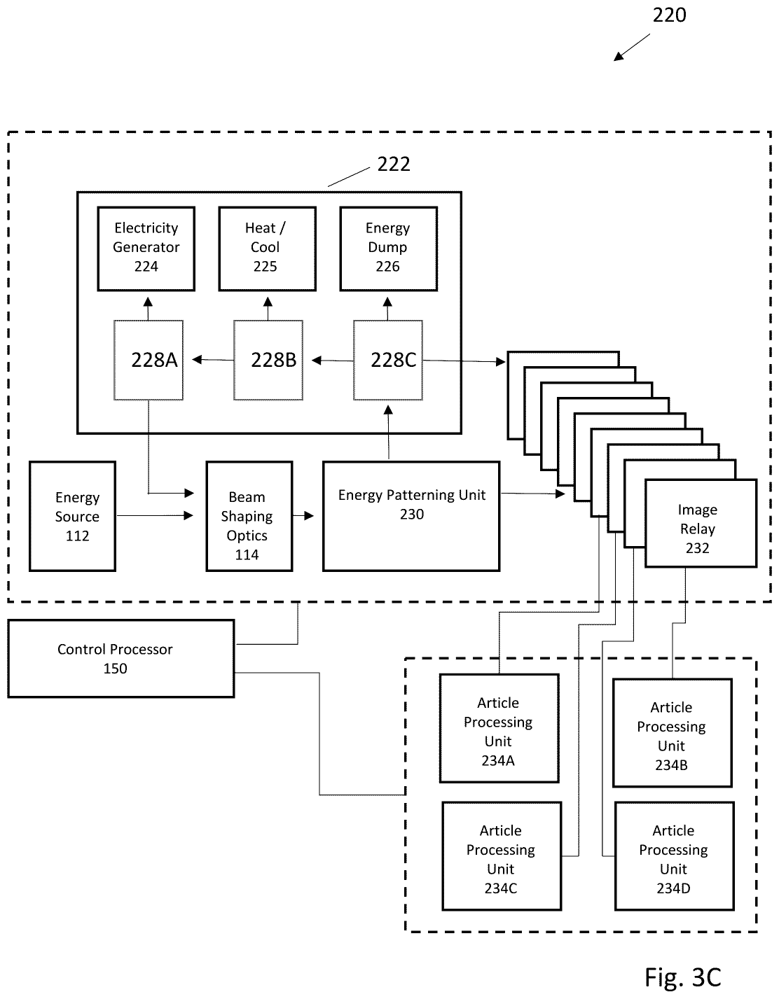

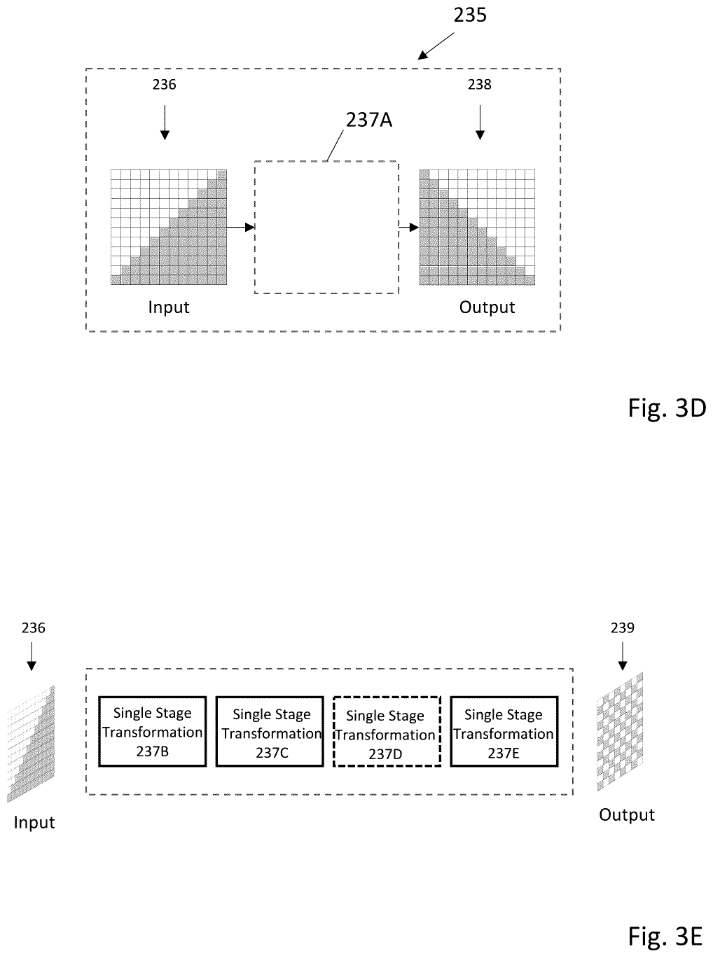

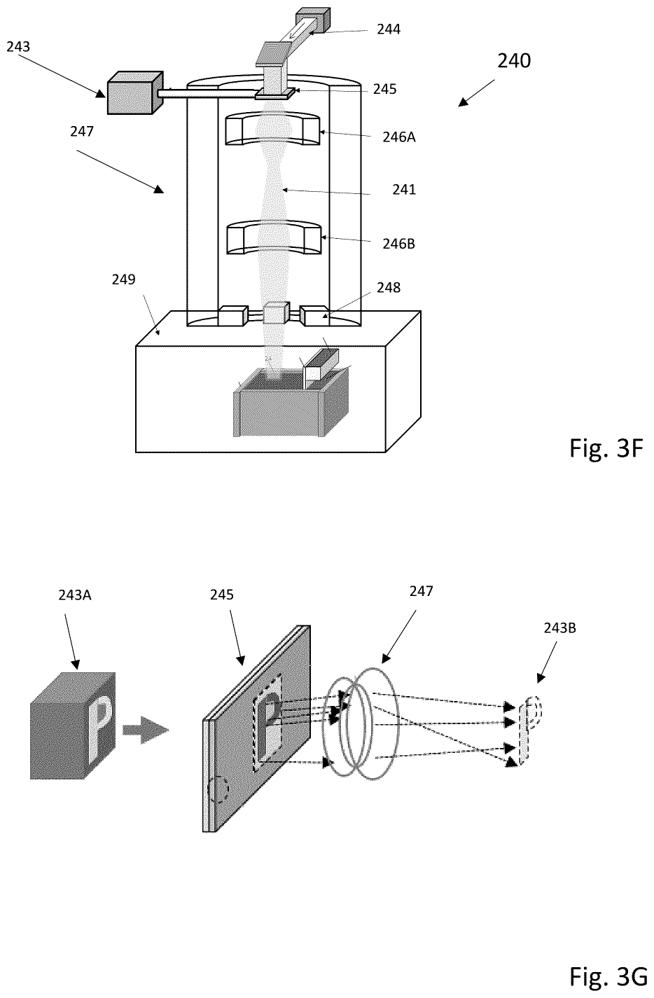

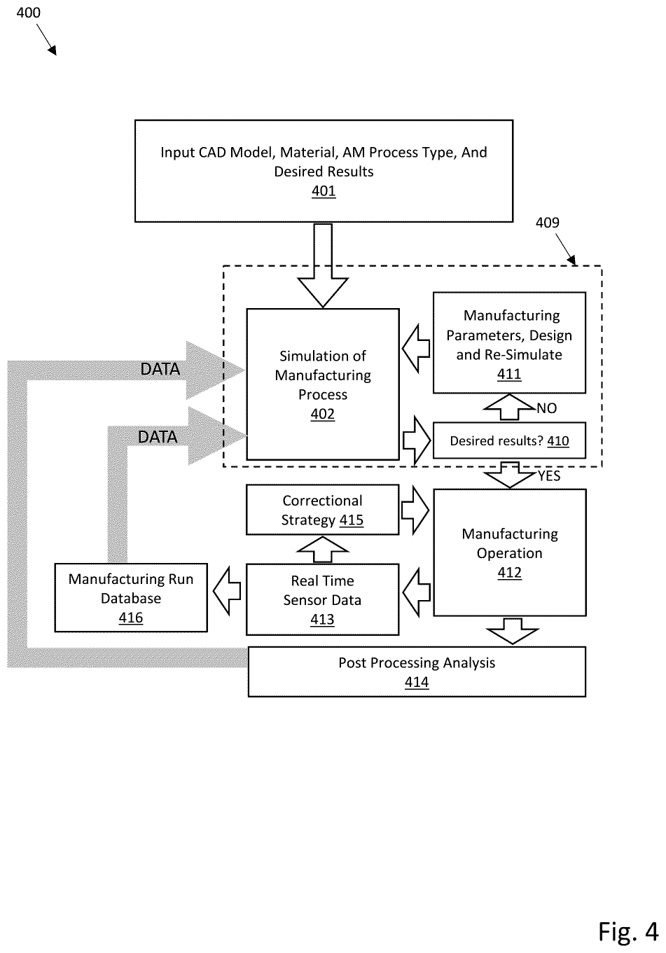

FIG. 3A is one embodiment of an additive manufacturing system 300 that uses multiple semiconductor lasers as part of an energy patterning system 310. A control processor 350 can be connected to variety of sensors, actuators, heating or cooling systems, monitors, and controllers to coordinate operation of multiple lasers 312, light patterning unit 316, and image relay 320, as well as any other component of system 300. These connections are generally indicated by a dotted outline 351 surrounding components of system 300. As will be appreciated, connections can be wired or wireless, continuous or intermittent, and include capability for feedback (for example, thermal heating can be adjusted in response to sensed temperature). The multiple lasers 312 can emit a beam 301 of light at a 1000 nm wavelength that, for example, is 90 mm wide by 20 mm tall. The beam 301 is resized by imaging optics 370 to create beam 303. Beam 303 is 6 mm wide by 6 mm tall and is incident on light homogenization device 372 which blends light together to create blended beam 305. Beam 305 is then incident on imaging assembly 374 which reshapes the light into beam 307 and is then incident on hot cold mirror 376. The mirror 376 allows 1000 nm light to pass, but reflects 450 nm light. A light projector 378 capable of projecting low power light at 1080p pixel resolution and 450 nm emits beam 309, which is then incident on hot cold mirror 376. Beams 307 and 309 overlay in beam 311, and both are imaged onto optically addressed light valve 380 in a 20 mm wide, 20 mm tall image. Images formed from the homogenizer 372 and the projector 378 are recreated and overlaid on light valve 380.

The optically addressed light valve 380 is stimulated by the light (typically ranging from 400-500 nm) and imprints a polarization rotation pattern in transmitted beam 313 which is incident upon polarizer 382. The polarizer 382 splits the two polarization states, transmitting p-polarization into beam 317 and reflecting s-polarization into beam 315 which is then sent to a beam dump 318 that handles the rejected energy. As will be understood, in other embodiments the polarization could be reversed, with s-polarization formed into beam 317 and reflecting p-polarization into beam 315. Beam 317 enters the final imaging assembly 320 which includes optics 384 that resize the patterned light. This beam reflects off of a movable mirror 386 to beam 319, which terminates in a focused image applied to material bed 344 in an article processing unit 340. The depth of field in the image selected to span multiple layers, providing optimum focus in the range of a few layers of error or offset.

The bed 390 can be raised or lowered (vertically indexed) within chamber walls 388 that contain material 344 dispensed by material dispenser 342. In certain embodiments, the bed 390 can remain fixed, and optics of the final imaging assembly 320 can be vertically raised or lowered. Material distribution is provided by a sweeper mechanism 392 that can evenly spread powder held in hopper 394, being able to provide new layers of material as needed. An image 6 mm wide by 6 mm tall can be sequentially directed by the movable mirror 386 at different positions of the bed.

When using a powdered ceramic or metal material in this additive manufacturing system 300, the powder can be spread in a thin layer, approximately 1-3 particles thick, on top of a base substrate (and subsequent layers) as the part is built. When the powder is melted, sintered, or fused by a patterned beam 319, it bonds to the underlying layer, creating a solid structure. The patterned beam 319 can be operated in a pulsed fashion at 40 Hz, moving to the subsequent 6 mm×6 mm image locations at intervals of 10 ms to 0.5 ms (with 3 to 0.1 ms being desirable) until the selected patterned areas of powder have been melted. The bed 390 then lowers itself by a thickness corresponding to one layer, and the sweeper mechanism 392 spreads a new layer of powdered material. This process is repeated until the 2D layers have built up the desired 3D structure. In certain embodiments, the article processing unit 340 can have a controlled atmosphere. This allows reactive materials to be manufactured in an inert gas, or vacuum environment without the risk of oxidation or chemical reaction, or fire or explosion (if reactive metals are used).

FIG. 3B illustrates in more detail operation of the light patterning unit 316 of FIG. 3A. As seen in FIG. 3B, a representative input pattern 333 (here seen as the numeral “9”) is defined in an 8×12 pixel array of light projected as beam 309 toward mirror 376. Each grey pixel represents a light filled pixel, while white pixels are unlit. In practice, each pixel can have varying levels of light, including light-free, partial light intensity, or maximal light intensity. Unpatterned light 331 that forms beam 307 is directed and passes through a hot/cold mirror 376, where it combines with patterned beam 309. After reflection by the hot/cold mirror 376, the patterned light beam 311 formed from overlay of beams 307 and 309 in beam 311, and both are imaged onto optically addressed light valve 380. The optically addressed light valve 380, which would rotate the polarization state of unpatterned light 331, is stimulated by the patterned light beam 309, 311 to selectively not rotate the polarization state of polarized light 307, 311 in the pattern of the numeral “9” into beam 313. The unrotated light representative of pattern 333 in beam 313 is then allowed to pass through polarizer mirror 382 resulting in beam 317 and pattern 335. Polarized light in a second rotated state is rejected by polarizer mirror 382, into beam 315 carrying the negative pixel pattern 337 consisting of a light-free numeral “9”.

Other types of light valves can be substituted or used in combination with the described light valve. Reflective light valves, or light valves base on selective diffraction or refraction can also be used. In certain embodiments, non-optically addressed light valves can be used. These can include but are not limited to electrically addressable pixel elements, movable mirror or micro-mirror systems, piezo or micro-actuated optical systems, fixed or movable masks, or shields, or any other conventional system able to provide high intensity light patterning. For electron beam patterning, these valves may selectively emit electrons based on an address location, thus imbuing a pattern on the beam of electrons leaving the valve.

FIG. 3C is one embodiment of an additive manufacturing system that includes a switchyard system enabling reuse of patterned two-dimensional energy. Similar to the embodiment discussed with respect to FIG. 1A, an additive manufacturing system 220 has an energy patterning system with an energy source 112 that directs one or more continuous or intermittent energy beam(s) toward beam shaping optics 114. After shaping, the beam is two-dimensionally patterned by an energy patterning unit 230, with generally some energy being directed to a rejected energy handling unit 222. Patterned energy is relayed by one of multiple image relays 232 toward one or more article processing units 234A, 234B, 234C, or 234D, typically as a two-dimensional image focused near a movable or fixed height bed. The bed (with optional walls) can form a chamber containing material dispensed by material dispenser. Patterned energy, directed by the image relays 232, can melt, fuse, sinter, amalgamate, change crystal structure, influence stress patterns, or otherwise chemically or physically modify the dispensed material to form structures with desired properties.

In this embodiment, the rejected energy handling unit has multiple components to permit reuse of rejected patterned energy. Relays 228A, 228B, and 22C can respectively transfer energy to an electricity generator 224, a heat/cool thermal management system 225, or an energy dump 226. Optionally, relay 228C can direct patterned energy into the image relay 232 for further processing. In other embodiments, patterned energy can be directed by relay 228C, to relay 228B and 228A for insertion into the energy beam(s) provided by energy source 112. Reuse of patterned images is also possible using image relay 232. Images can be redirected, inverted, mirrored, sub-patterned, or otherwise transformed for distribution to one or more article processing units. 234A-D. Advantageously, reuse of the patterned light can improve energy efficiency of the additive manufacturing process, and in some cases improve energy intensity directed at a bed, or reduce manufacture time.

FIG. 3D is a cartoon 235 illustrating a simple geometrical transformation of a rejected energy beam for reuse. An input pattern 236 is directed into an image relay 237 capable of providing a mirror image pixel pattern 238. As will be appreciated, more complex pixel transformations are possible, including geometrical transformations, or pattern remapping of individual pixels and groups of pixels. Instead of being wasted in a beam dump, this remapped pattern can be directed to an article processing unit to improve manufacturing throughput or beam intensity.

FIG. 3E is a cartoon 235 illustrating multiple transformations of a rejected energy beam for reuse. An input pattern 236 is directed into a series of image relays 237B-E capable of providing a pixel pattern 238.

FIGS. 3F and 3G illustrates a non-light based energy beam system 240 that includes a patterned electron beam 241 capable of producing, for example, a “P” shaped pixel image. A high voltage electricity power system 243 is connected to an optically addressable patterned cathode unit 245. In response to application of a two-dimensional patterned image by projector 244, the cathode unit 245 is stimulated to emit electrons wherever the patterned image is optically addressed. Focusing of the electron beam pattern is provided by an image relay system 247 that includes imaging coils 246A and 246B. Final positioning of the patterned image is provided by a deflection coil 248 that is able to move the patterned image to a desired position on a bed of additive manufacturing component 249.

Other manufacturing embodiments involve collecting powder samples in real-time in a powder bed fusion additive manufacturing system. An ingester system is used for in-process collection and characterizations of powder samples. The collection may be performed periodically, and the results of characterizations result in adjustments to the powder bed fusion process. The ingester system can optionally be used for one or more of audit, process adjustments, or actions such as modifying printer parameters or verifying proper use of licensed powder materials.

In certain embodiments, an additive manufacturing machine such as disclosed herein can be programed to adjust laser power flux and dwell time, print order among other machine parameters during the manufacturing process, as well as support structure, orientation, porosity, and overall part topology among other geometrical parameters during the part pre-processing. These adjustments can be guided with reference to a physics model optimized for additive manufacturing processes, including but not limited to powder bed fusion.

For example, in one embodiment the additive manufacturing process can be simulated using data related to the Computer Aided Design (CAD) geometry for the powder bed, material type with a specified metallurgy, material powder profile, printer model (or printer capabilities), and desired resultant material properties such as stress distribution, thermal warpage, or crystal structure. Simulation results can be compared to a part material specification, and power flux, dwell time, porosity, and print order along with other geometrical parameters such as part orientation, support structure, and part topology can be adjusted in the simulated machine and the simulation repeated. Machine learning algorithms can allow for previous simulations (and the results of previous experiments stored in databases) to be accessed by these algorithms to minimize the number of cycles required and allow for faster convergence on the optimum manufacturing parameters to create the desired parts with the desired properties.

If part functionality requirements are also known, another level of simulation can be carried out to optimize the design of the part for both the end use case, and for the additive manufacturing process. As an example, a part could benefit from various levels of internal pre-stressing developed/imbedded during the additive manufacturing process, the use of which would be realized in the end-use application. A stress state throughout the part can be specified to be within a specific tolerance, and in certain embodiments a part can be manufactured to have a two or three-dimensional stress map within a given tolerance or spatially defined set of tolerances.

Once a simulation is performed with sufficient accuracy, the results will typically hold for repeated machine runs. This is particularly useful for high throughput techniques of additive manufacturing such as disclosed herein, since results of one simulation can be re-used multiple times.

Furthermore, a single print bed simulation might contain multiple parts of different types. If a part of a given type has been previously simulated or printed, initial conditions can be set for that part using the pre-solved conditions from past parts. Alternative solutions are to design all parts to interconnect in the same way such that they are separable enabling the division and superposition of simulation results. Once a solution for a given part is obtained, if packed in an appropriate configuration in the bed, it is possible to apply the theory of superposition to packing and applicable analyses. Additive manufacturing process for a part in one bed can be applied to that in a completely different bed, surrounded by completely different parts. Modeling and manufacture efficiency can be improved in some embodiments by ensuring that appropriate boundary conditions are applied for the part such that its connection to surrounding parts is always the same.

As an example of pre-processing and design optimization, producing a part with minimal residual stresses using simulation, topology changes, and machine parameter modification can be accomplished using one or more steps of the following described method. First, a Computer Aided Design (CAD) model, a material type with a specified metallurgy, a material powder profile, Additive Manufacturing (AM) process type, and desired part design, porosity, and residual stress expectation are input into an optimization algorithm of a simulation. This optimization algorithm can utilize background data from previous simulation runs to inform the results of the current simulation. Knowing the type of additive manufacturing process and part material/physical properties, processing parameters can be derived from previous results. The AM process is then simulated and resultant stress distribution, crystal structure, porosity, and other relevant properties are evaluated. Based on the design requirements, the AM process parameters such as laser power, dwell time, or event timing can be modified, and the process re-simulated. Alternatively, the part (including support structure) can be topologically optimized, with or without modification to the processing parameters, and the AM process re-simulated. If simulated parts meet the desired specification, the process is complete and the resulting process parameters can be passed to the AM machine to carry out the manufacturing process. If simulated parts are not acceptable, then the data can be fed back, and the process repeated.

As will be understood, while the foregoing described modeling techniques can be done on on-board computers in the additive manufacturing machine, it could also be offered as a remote service. Due to the computationally intensive nature of these calculations, the process would greatly benefit from the ability for users to submit “jobs” to an available super computer that could process the data and return the result after the iterations were completed and a solution converged upon.

In another embodiment, additive manufacturing can include in-process monitoring with correctional strategies. Post-process data collection and comparison to experiments can also be supported.

In-process monitoring relies on the use of a suite of sensors such as, but not limited to, vision, IR, thermocouples, pressure sensors to evaluate melt pool characteristics, powder bed/base plate/build chamber temperatures, thermal radiation profiles, and system gas pressure among many other parameters. Evaluating and determining if the build process is proceeding correctly and taking the appropriate corrective actions helps ensure that parts created are true to form and maintain the desired shape.

Sensor monitoring for in-process control can monitor both an area currently being printed (i.e. illuminated with an energy beam such as laser light or e-beam), and the next area to be printed. Careful measurement of the next location to be printed, correlated with simulation and table value lookup can aid in adjusting the print schedule on the fly, adjusting the delivered power flux to match the temperature in upcoming zones to alleviate over/under melting scenarios which lead to degradation in part resolution and increase of thermally induced stresses. Other examples of potential actions include selective changes to the heating/cooling of zones in the chamber walls, substrate, or ceiling to spatially manage heat loss.

In those embodiments where a vision system and in-process monitoring are able to visually evaluate how effectively the pixels of a given layer were printed, actions can be triggered such as reprinting of a pixel prior to new layer going down, or extra attention/action in following layer to ensure that that pixel printed as desired. In this method, random and unforeseen errors introduced during the printing process are mitigated.

Post processing analysis allows for the correction of computational models and corrective action algorithms to better reflect the real-life end result. Destructive stress analyses (e.g. tensile, compressive, torsion tests) can be used, as well as non-destructive stress analysis techniques that allow evaluation of parts. This can include calipers for key dimensions, coordinate measuring machines (CMM), vision systems for metrology, and methods that allow for deep penetration into materials such as Neutron Diffraction (ND). Neutron diffraction in particular is a method that can be used to determine internal stress distributions in crystalline structures by evaluating how neutrons penetrate and scatter off of atoms in the crystalline lattice. It can penetrate relatively deep (60 to 100 mm) and can be used to measure stress distributions in complex shapes made from steel, aluminum, and titanium. Feedback from ND is useful for the evaluation of additively manufactured parts since it can be used to calculate the internal stress fields of a part if the dimensions for penetration depth are correctly observed. Additionally, microcomputed tomographic (μ-CT) scanners can be used to evaluate the tomography of the part post processing.

FIG. 4 illustrates an exemplary flow chart 400 of a system and method accomplished using one or more operations on, or analysis of, input parameters, pre-manufacturing simulations, in-process monitoring and control, post processing data collection, and selected design tolerances to inform a pre-processing algorithm. Information related to a part can be variously provided or received by suitable operating or simulating modules configured to implement methods and systems described herein, and can include but are not limited to a Computer Aided Design (CAD) model, a material type with a specified metallurgy, a material powder profile, and an Additive Manufacturing (AM) process type. Desired results are input into an optimization algorithm 401. This algorithm can use background data from previous runs to inform the results of a simulation. Knowing the type of additive manufacturing process and part material/physical properties, processing parameters can be derived from previous results. The AM process is then simulated and resultant stress distribution, crystal structure, porosity, selected design tolerances, and other relevant properties are evaluated from the simulation 402.

The simulation may be a finite element analysis, hydrodynamic simulation or multi-physics model. For example, various aspects of the additive manufacturing process may be simulated using different techniques, which are then integrated to generate an accurate simulation of a printed part outcome. For example, radiation transfer through the system including loses may be simulated using a Monte Carlo method, for example Markov Chain Monte Carlo. Cooling and heating during part printing can be simulated using computational fluid dynamics, and multiphysics simulations can be used to simulate physical stresses caused expansion and contraction caused by temperature distributions during pre-heating, melting, and cooling as well as simulating the effects of post-processing (for example hot-isostatic pressing (HIP)). The simulation results are evaluated (step 410) and if not acceptable, the manufacturing parameters and/or design of the part are modified and the manufacturing process is re-simulated 411, as incorporated in an overall simulation feedback loop 409. If the results are acceptable, then they are passed to the AM machine to perform the manufacturing operation 412. Since the overall goal is to generate useful parts, and because some level of random error is inevitable, the manufacturing operation can be monitored using various sensors 413 to determine if there is a failure in the printing process, and either alert the operator with corrective measures, or automatically take corrective measures 415. The real-time sensor data could include temperature measurements, pressure measurements, gas species measurements, thermal radiation spectrum and intensity measurements, along with various laser diagnostics for spatial and temporal profile measurements. Further sensor data sources include data from manufacturing system robotics such as the powder distribution mechanism, visual diagnostic systems measuring system parameters including melt pool data. The success and failures of the manufacturing process as represented by the logged sensor data can be fed into a database for logging real time data on the manufacturing run 416. From there the data can be fed back into the simulation feedback loop 409, and more specifically to the correctional logic used to arrive at a self-consistent solution meeting the required design constraints. Once the manufacturing operation 412 is completed, the part can be analyzed in a post process analysis 414 which can include destructive techniques, slicing, SEM, TEM, DTEM, and non-destructive techniques such as Neutron Diffraction and μ-CT scanning. Data from the post processing analysis 414 is stored in a database 416 and accessed by the simulation feedback loop 409 such that feedback can be accounted for based on the simulation, how the part actually printed as determined with real-time sensor data 413, and using any resultant analyzed properties. Data from the simulation and feedback from previously printed parts can then be used to determine appropriate print parameters, including powder choice, laser parameters e.g. flux, pulse length, dwell time etc., print sequencing e.g. the sequencing of patterned print energy, and post-processing parameters such as HIP temperature to consistently meet the required geometry, density, and other metallurgical requirements of a printed part.

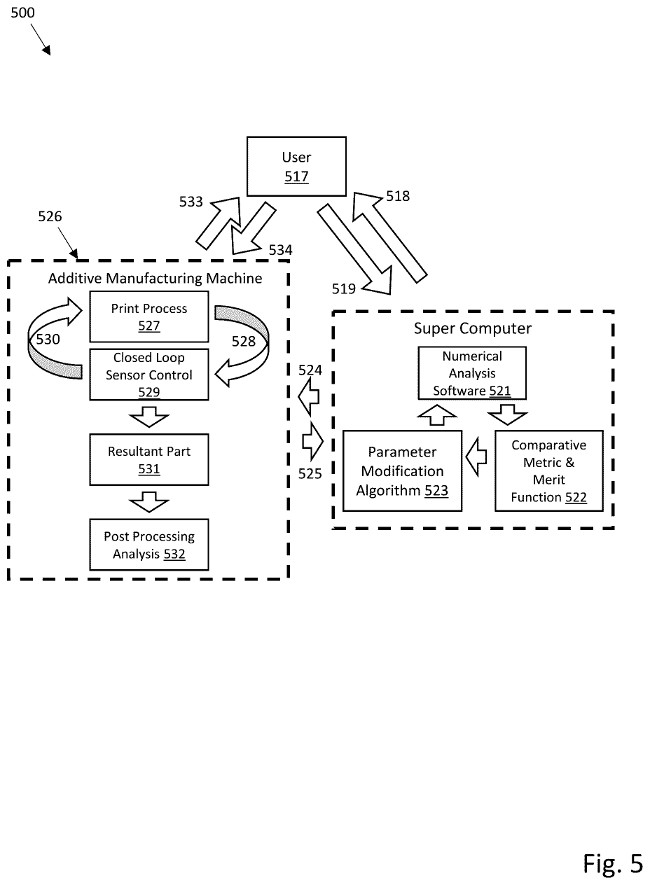

FIG. 5 illustrates an example 500 of how a user would interact with the disclosed system and methods. A user 517 is able to exchange data 519 with a remotely accessed computer 520 by sending CAD files, specifying an additive process to simulate, and providing a resultant acceptable stress map and allowable manufacturing design tolerances. Using multi-physics numerical analysis software 521, the computer 520 can evaluate the manufacturing process of the desired CAD part to be printed. Once completed, a comparative metric 522 compares the output of the simulation with the user supplied requirements and tolerances. If the simulated part is out of compliance, the nature of the non-compliance is sent to a parameter modification algorithm 523 which can modify the machine parameters used in the simulation by 521 both globally and temporally. Modified parameters can include laser intensities, pulse shapes, pulse durations, gas pressures, gas compositions, bed temperatures, powder temperatures, print order in a given layer, and specific to diode additive manufacturing, print order within a given image. Geometrical parameters that can be modified can include the support structure used or orientation of the part. In certain embodiments, if intent for part design is given and coupled into the model, then overall part topology could be modified. Once the appropriate modifications are made to the simulation parameters, the numerical analysis software 521 is re-run, and the results re-compared with the comparative metric 522. If the solution is not achieved, then the process is repeated. However, if the results of 521 meet the user specified comparative metrics 522, then the successful manufacturing information can be passed to the additive manufacturing machine 526 via data channel 524. Feedback to user 517 on the simulation process and results can be given by 518 to the user such that simulation is not necessary for future runs, or appropriate initial conditions can be chosen. Once the manufacturing information is sent via 524 from the computer 520 and the additive manufacturing machine 526, the print process 527, can begin. During the print process, a closed loop sensor control 528, 529, 530 is used to monitor the process taking into account system temperatures, pressures, gas compositions, melt pool monitoring, and visual inspection of the build platform, whether manual or automated using computer vision. This process ensures that the additive manufacturing process performs to within standards of operation, and to detect a machine or build part failure, evaluating/executing methods for repair, or alerting an operator that the machine needs attention. Once the manufacturing process is complete, the resultant part 531 is removed from the build platform and either analyzed in a post processing analysis 532 or returned to the user 517 via 533, or both depending on if the post processing analysis 32 is destructive or not. Sensor data from the closed loop sensor control 519 and the data from the post processing analyses 532 can be stored in a database accessible through 525 to the computer 520 to inform the numerical analysis software, and through 533 to the user 517 to evaluate the progress of their run, and part quality. The user 517 submits feedback on part quality and usability via 534 to assist in further improving the process.

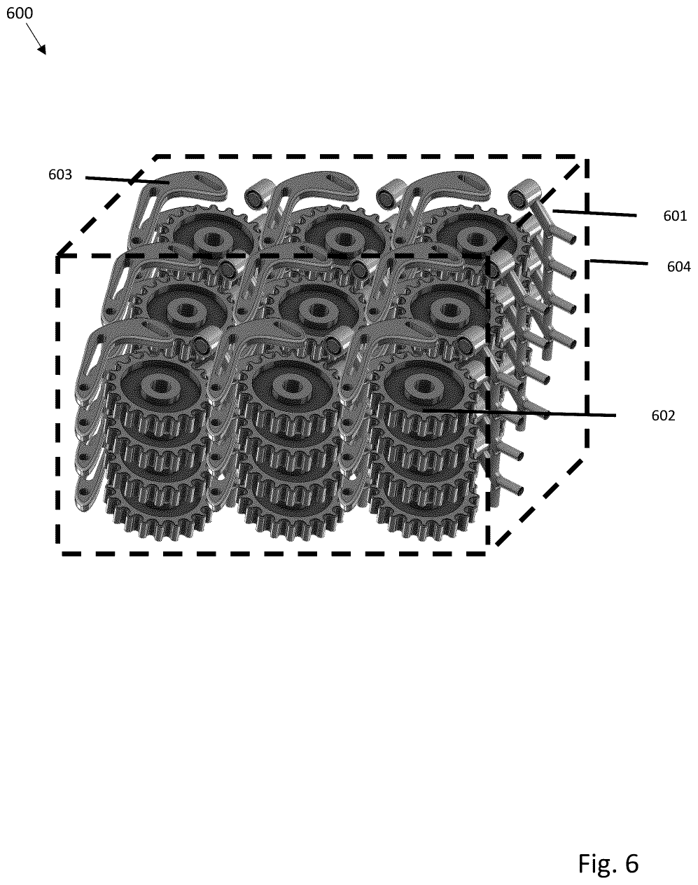

FIG. 6 illustrates an example 600 of multiple different parts packed into a single build volume. A fuel injection nozzle 601, a 20-tooth gear 602, and a mechanical armature 603 are geometrically oriented within build volume 604 as specified by the printable volume of the printer. In this example, an additive manufacturing printer is used to print these components in 316 stainless steel. The three component types are packed in such a way that not only meets geometrical concerns, but also coordinates the temporal thermal load history of each part such that the desired end state internal stress profiles are achieved in each part.

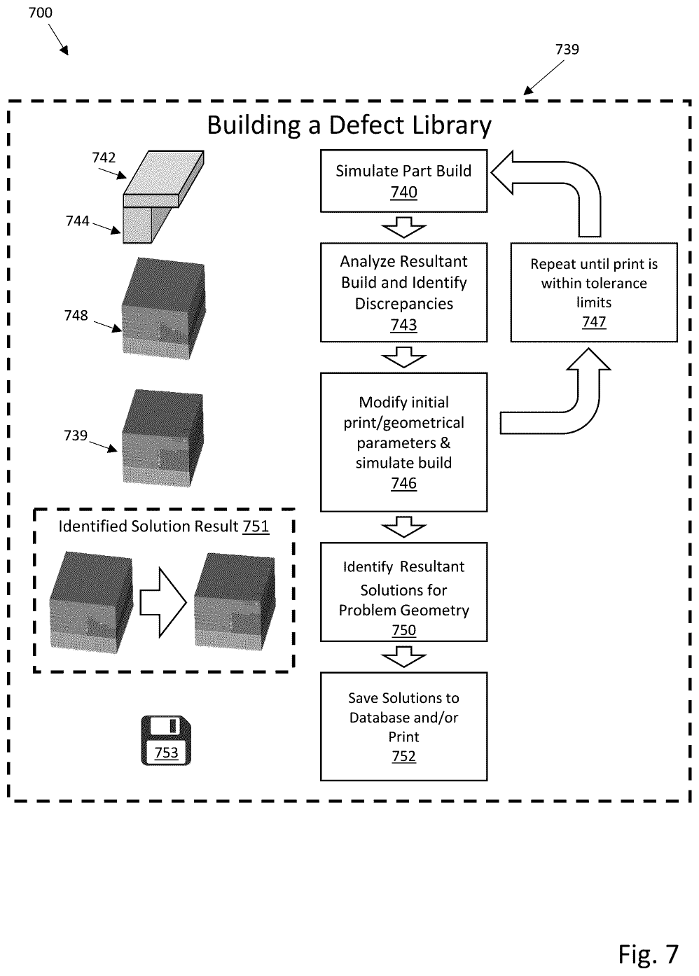

FIG. 7 illustrates an example 700 of use of an algorithm 739 for identifying defects, solving for the corrective parameters, printing and/or creating a library of defect correction strategies. The building of the part is first simulated without any pre-determined correction strategies 740. The example part is composed of two main geometrical features, a base pillar 741, and an overhang component 742. The resultant internal stresses and part geometries resulting from simulating the build part are then analyzed 743. The part in this example suffered no change in the main column 744 during the print simulation, however using standard print properties to manufacture the overhang component 745, it is noticed that there is significant over-melting and deepening of the melt pool. Corrective action is then taken by to modify the initial print properties 746; in this case it is to lower the laser intensity that is used to manufacturing the overhang by a factor of 2. The simulation process is repeated 747, and the part is re-analyzed 743. After re-simulating, it is found that the base pillar 48 is still within tolerances, and now the overhang 749 is within tolerance limits as well. The solution for solving this geometrical feature defect is identified 750 and 751, and the solution is saved to a database 752/753, and/or the article is printed.

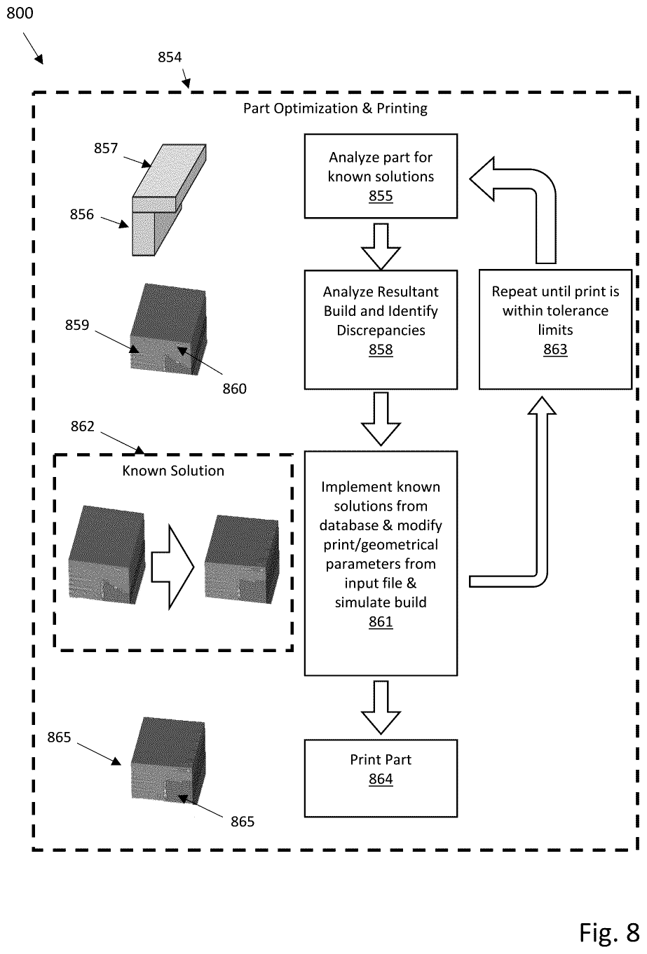

FIG. 8 illustrates an example of an algorithm 855 for printing a part utilizing an algorithm solver/optimizer and drawing from a library of defect correction strategies. The building of the part is first simulated without any pre-conceived correction strategies 855. The example part in this instance is composed of two main geometrical features, a base pillar 856, and an overhang component 857. The resultant internal stresses and part geometries resulting from simulating the build part are then analyzed 858. The part in this example suffered no change in the main column 859 during the print simulation, however using standard print properties to manufacture the overhang component 860, it is noticed that there is significant over-melting and deepening of the melt pool. The database of known solutions is then queried 861, and the appropriate strategy is selected for a known solution 862 is selected. Corrective action is then taken by modifying the initial print properties to reflect the changes in the known solution; in this case, it is to lower the laser intensity that is used to manufacturing the overhang by a factor of 2. The simulation process is repeated 863 to verify good build quality within tolerance limits, and the part is re-analyzed 858. After re-simulating, it is found that the base pillar 865 is still as desired, and now the overhang 866 is within tolerance limits as well. The article of verified quality achieved by the current print parameters is ready to be printed. The article is printed 864.

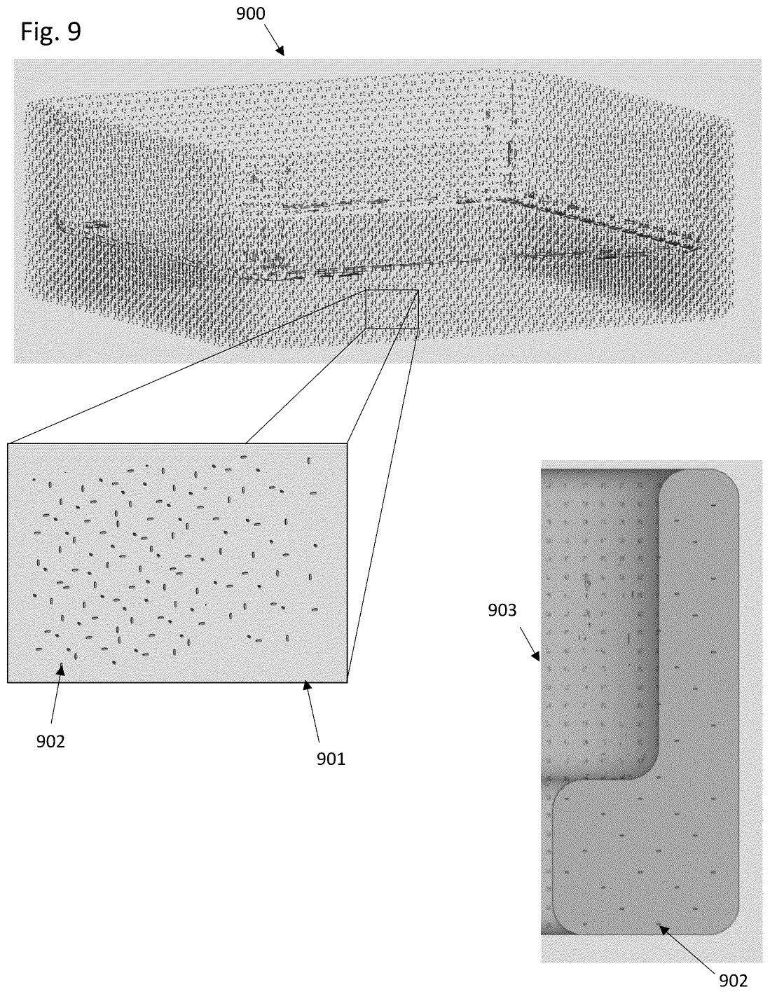

FIG. 9 illustrates an embodiment of a porosity unit cell 901, consisting of a matrix of voids 902, applied as an infill for a part to be manufactured 900 for use in the simulation and additive manufacturing system and a cross section of the infill applied to a part 903. In some embodiments, the porosity unit cell 901 is derived by scanning the manufactured part with a microcomputed tomographic (μ-CT) scanner for porosity before and after undergoing a heat treatment method, but other embodiments can utilize a different tomography analysis method. For example, analysis of a printed part can be carried out via other testing methods, for example ultrasound or scanning electron microscopy (SEM). Other inputs may be used to predict the porosity characteristics, for example, the properties of the powder used as feedstock for the metal part or other process parameters that are known to have an effect on the printed porosity.

The data from the porosity analysis is used to generate the porosity unit cell 901, for example by generating an STL or other suitable geometric representation file of the porosity unit cell 901. The unit cell porosity cell file can be then stored into a unit cell library in some embodiments. Once in the unit cell library, the unit cell can then be applied as an infill to a part to be manufactured 900. A simulation can be run to account for the distortion of the part during printing and from post-processing methods, for example the heat treatment method (e.g. hot isostatic pressing (HIP) methods) for example shrinkage, expansion, changes in density, pore size and shape, and other parameters can be predicted. Finite Element Analysis (FEA), Fast Fourier Transform (FFT) or other appropriate methods of predicting or simulating the pre- and post-process composition, geometry, and shape of part can be used. In some embodiments, the simulation tool would apply the infill along with other simulation parameters and work backwards and forwards in a closed loop to derive a solution of how to alter the geometry to allow for the desired geometry to be achieved after the heat-treating process. The simulation would then allow the scaled, un-infilled, and altered geometry to be exported as an STL or other appropriate output file to be used as input to generate instructions for metal 3-D printing of a pre-deformed part. For example, the STL or other file may be used as input for appropriate slicer software to prepare the file for printing by converting the part geometry into a series of instructions for controlling various aspects of the 3-D printing process, for example print head positioning, galvo movement, flux, dwell time of a laser or other aspects of the 3-D printing process. The part can then be printed in a pre-distorted form to account for any deformation during printing and post-processing so that the finished part meets the required specification, for example with respect to metal density, lack of porous defects and geometry. Additionally, in some embodiments, the part will be scanned before and after HIP, and the results fed back into the simulation library to make the simulation more accurate.

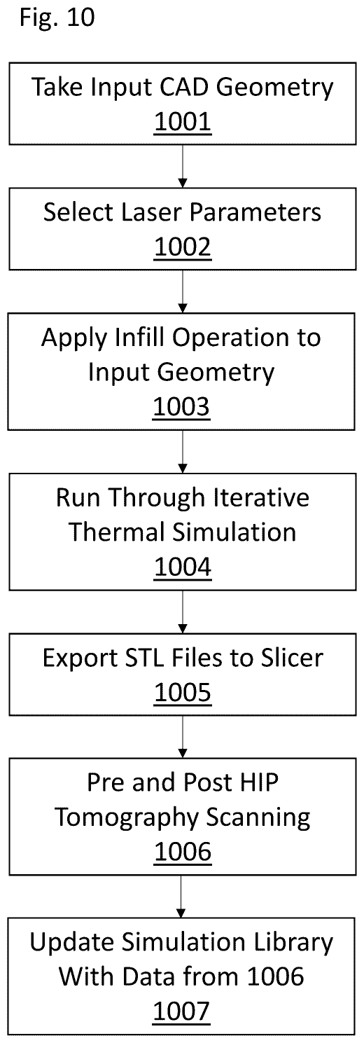

FIG. 10 illustrates a block diagram 1000 of an update process for the counter deformation calculations of the simulation. In step 1001, CAD geometry of a part to be manufactured is uploaded. Then, simulated laser parameters are configured in step 1002. In some embodiments, step 1002 further comprises establishing a thickness of the walls, overhang, density, porosity, geometry or other parameters of the part to be manufactured, among other design tolerances. In step 1003, the porosity profile is selected and applied to the CAD geometry of the part to be manufactured. The porosity profile exists in the simulation as a unit cell capable of being applied to any part geometry or design feature. This step represents the result of 3-D printing a metal part with particular parameters such as laser intensity, dwell time, flux, pulse length, whether or not a particular area of the powder bed has one or more pulses applied, the patterning applied to the laser, layer thickness, chemical structure of the input metal powder, powder grain size, melt pool size, or other manufacturing variables used to result in a 3-D printed metal part with a particular porosity. Then in step 1004 the part is run through an iterative thermal simulation in which additional heating (e.g. a furnace recipe) is specified that will close the pores and causing the part to shrink and resulting in a smaller geometry. This smaller geometry will be denser and shrink proportionately to the pore size and distribution based on the features. The shrinkage of the part may be variable depending on, for example, part thickness over a particular axis, distribution of pores throughout the part, pore size or other parameters. Over time, new data may be added to a simulation library to allow the model to learn shrinkage, expansion or deformation based on various factors. Upon each new iteration, the simulation can scale the input part up or down and reapply the infill until the simulation converges on an original input geometry for the final part. In step 1005, a print parameter file, for example an STL file of the part is exported to the appropriate slicing software to prepare a computerized model of the part to be manufactured for printing. This computerized model is designed to adhere to the predetermined tolerances after the part undergoes heat treatment, (e.g. HIP). In step 1006, the computerized model of the part to be manufactured can be manufactured using area printing or another appropriate 3-D printing process, and the part would undergo a μ-CT scan or other testing for example, ultrasound, scanning electron microscopy or other non-destructive testing before and after the manufactured part undergoes heat treatment. Finally, in step 1007, the simulation is then updated with the data from testing before and after heat treatment to improve the simulation accuracy.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

1. A method of additive manufacture, comprising the steps of:
providing information related to a part, the information including CAD files, material type and metallurgy, selected additive manufacturing process type, and tolerances of selected design features;
simulating manufacture of a part using the selected additive manufacturing process;
comparing the simulated manufactured part to selected design tolerances;
if the simulated manufactured part is outside selected design tolerances, adjusting simulation parameters;
repeating simulated part manufacture and adjustment of simulation parameters until evaluated simulation results indicate the simulated manufactured part is within selected design tolerances;
manufacturing the part while using a real-time sensor monitoring system;
providing post processing analysis of selected design features; and
providing data from the real-time sensor monitoring system and the post processing analysis of selected design features to improve simulated manufacture of the part.

2. The method of claim 1, wherein simulation and manufacturing parameters relate to an energy patterning unit able to provide two-dimensional patterned energy beams.

3. The method of claim 1, wherein design tolerances include stress.

4. The method of claim 1, wherein design tolerances include part geometry.

5. The method of claim 1, wherein design tolerances include topological positioning of the part.

6. The method of claim 1, wherein design tolerances include porosity.

7. The method of claim 1, wherein real-time sensor monitoring system can provide measurements related to one or more of temperature, pressure, gas species, thermal radiation spectrum and intensity measurements.

8. The method of claim 1, wherein real-time sensor monitoring system can provide measurements related to one or more of laser diagnostics for spatial and temporal profile measurements.

9. The method of claim 1, wherein real-time sensor monitoring system can provide data specific to an additive manufacturing system such as operation of a powder distribution mechanism or visual diagnostic system performance.

10. The method of claim 1, wherein simulation parameters can include at least one of directed beam intensities, beam pulse shapes, beam pulse durations, gas pressure, gas composition, bed temperature, power temperature, print order in a given layer, print order within a given image, geometrical parameters such as support structure or orientation of the part, porosity, and overall part topology.

11. The method of claim 1, wherein post processing analysis of selected design features includes a tomographic analysis.

12. The method of claim 11, wherein the tomographic analysis is used to generate a porosity unit cell.

13. The method of claim 12, wherein the porosity unit cell is used as an infill in a simulation of a printed part to determine a deformation of a part-during printing and post-processing; and,
the determined deformation is used to adjust the geometry of a to be printed part to meet a design-tolerance.

14. A method of building a defect library for additively manufactured parts, comprising the steps of:
providing information related to a part, the information including CAD files, material type and metallurgy, selected additive manufacturing process type, and tolerances of selected design features;
simulating manufacture of a part using the selected additive manufacturing process;
comparing the simulated manufactured part to selected design tolerances;
if the simulated manufactured part is outside selected design tolerances, adjusting simulation parameters;
repeating simulated part manufacture and adjustment of simulation parameters until evaluated simulation results indicate the simulated manufactured part is within selected design tolerances;
saving solutions within selected design tolerances to a defect library database.

15. The method of claim 14, wherein simulation and manufacturing parameters relate to an energy patterning unit able to provide two-dimensional patterned energy beams.

16. The method of claim 14, wherein design tolerances are selected from one or more of stress, part geometry, topological positioning, and porosity.

17. A method of simultaneous additive manufacture of multiple parts, comprising the steps of:
providing information related to the multiple part, the information including CAD files, material type and metallurgy, selected additive manufacturing process type, and tolerances of selected stress features;
simulating manufacture of the multiple parts using the selected additive manufacturing process, while optimizing for both multiple part packing and thermal load history;
comparing the simulated manufactured part to selected stress tolerances;
if the simulated manufactured part is outside selected design tolerances, adjusting simulation parameters; and
repeating simulated part manufacture and adjustment of simulation parameters until evaluated simulation results indicate the simulated manufactured part is within selected stress tolerances.

18. The method of claim 17, wherein simulation and manufacturing parameters relate to an energy patterning unit able to provide two-dimensional patterned energy beams.

19. The method of claim 17, further comprising the steps of:
manufacturing the part while using a real-time sensor monitoring system;
providing post processing analysis of selected design features; and
providing data from the real-time sensor monitoring system and the post processing analysis of selected design features to improve simulated manufacture of the part.

20. The method of claim 19, wherein real-time sensor monitoring system can provide measurements related to one or more of temperature, pressure, gas species, thermal radiation spectrum and intensity measurements.

21. The method of claim 19, wherein real-time sensor monitoring system can provide measurements related to one or more of laser diagnostics for spatial and temporal profile measurements.

22. The method of claim 17, wherein simulation parameters can include at least one of directed beam intensities, beam pulse shapes, beam pulse durations, gas pressure, gas composition, bed temperature, power temperature, print order in a given layer, print order within a given image, geometrical parameters such as support structure or orientation of the part, porosity, and overall part topology.

23. A method of additive manufacture using multiple lasers patterned to form a two-dimensional image, comprising the steps of:
providing and receiving information related to a part, the information including CAD files, material type and metallurgy, selected additive manufacturing process type, and tolerances of selected design features;
simulating manufacture of a part using the selected additive manufacturing process;
comparing the simulated manufactured part to selected design tolerances and adjusting simulation parameters when the simulated manufactured part is outside selected design tolerances, wherein at least one of the simulation parameters comprises a patterned two-dimensional image;
repeating simulated part manufacture and adjustment of simulation parameters until evaluated simulation results indicate the simulated manufactured part is within selected design tolerances;
manufacturing the part using the patterned two-dimensional image while using a real-time sensor monitoring system;
providing post processing analysis of selected design features; and
providing data from the real-time sensor monitoring system and the post processing analysis of selected design features to improve simulated manufacture of the part.
